(19) United States
(12) Patent Application Publication
(10) Pub. No.: US 2026/0255930 A1
(43) Pub. Date: Aug. 27, 2026

(54) PUSH-PULL DEVICE AND SUBSTRATE PROCESSING MODULE

(71) Applicant: EBARA CORPORATION, Tokyo (JP)

(72) Inventors: YOSHITAKA KITAGAWA, Tokyo (JP); MATSUTARO MIYAMOTO, Tokyo (JP)

(73) Assignee: EBARA CORPORATION, Tokyo (JP)

(21) Appl. No.: 19/548,970

(22) Filed: Feb. 25, 2026

(30) Foreign Application Priority Data
Feb. 26, 2025 (JP) 2025-028512

(51) Int. Cl. H10P 72/76; H10P 70/00

(52) U.S. Cl. CPC H10P 72/7626; H10P 70/20; H10P 72/7618

(57) ABSTRACT

A push-pull device includes a free joint structure, an air bearing cylinder, and a fixing bracket that receives a radial load acting on a rod structure.

### CROSS-REFERENCE TO RELATED APPLICATION

This application claims the priority benefit of Japan application serial no. 2025-028512, filed on Feb. 26, 2025. The entirety of the above-mentioned patent application is hereby incorporated by reference herein and made a part of this specification.

### BACKGROUND

### Technical Field

The present disclosure relates to a push-pull device and a substrate processing module.

### Related Art

An air cylinder may be mentioned as one example of a drive source of a push-pull mechanism that pushes and pulls a target object. The air cylinder includes a piston rod and a cylinder housing that accommodates the piston rod. By supplying a compressed gas into the cylinder housing, the piston rod is configured to move forward, and to move backward by a biasing force of a biasing member (for example, a spring) provided separately from the air cylinder.

As another configuration example of the air cylinder, a configuration may be mentioned in which the piston rod is caused to move forward and backward only by a compressed gas. Such an air cylinder, for example, does not have a biasing member, and has a configuration in which the compressed gas is supplied to/discharged from opposing spaces through a partition wall arranged in the cylinder housing.

[Patent Document 1] Japanese U.S. Pat. No. 7,023,592

However, in the air cylinder having such a configuration, there is a risk that the piston rod, due to its movement, may slide against the cylinder housing (more specifically, a guide portion). In this way, when sliding friction occurs between the piston rod and the cylinder housing, there is a risk that the movement of the piston rod cannot be accurately controlled.

Accordingly, in order to solve such a problem, there exists an air bearing cylinder employing an air bearing that supports a piston rod with a compressed gas supplied into a cylinder housing. However, such an air bearing cylinder has a problem that radial rigidity for supporting the piston rod is low.

When a radial load acts on the piston rod during assembly of a push-pull mechanism or during driving of the push-pull mechanism, there is a risk that the piston rod may collide with the cylinder housing. When the piston rod and/or the cylinder housing is damaged due to such a collision, there is a risk that the push-pull mechanism may cause a malfunction. As a result, there is a risk that an operating speed of the piston rod may be delayed, and an alarm may be generated or an operation of the push-pull mechanism may stop.

Particularly, in the case of the air bearing cylinder, compared to a length of the piston rod in the cylinder housing, a gap (bearing gap) where the piston rod is supported by an air film is very small. Hence, for example, when the air bearing cylinder is assembled, if the piston rod in an inclined state is inserted into the cylinder housing, there is a risk that the piston rod and/or the cylinder housing may be damaged.

Hence, it is necessary to carefully assemble the air bearing cylinder so that the cylinder housing and the piston rod are arranged coaxially, that is, their axial centers coincide in a vertical direction. However, even if the air bearing cylinder is carefully assembled, or during an operation of the air bearing cylinder after assembly, there is a risk that the piston rod and/or the cylinder housing may be damaged.

### SUMMARY

A push-pull device includes a free joint structure, an air bearing cylinder connected to the free joint structure, and a fixing bracket that receives a radial load acting on a rod structure connected to the air bearing cylinder.

### BRIEF DESCRIPTION OF THE DRAWINGS

FIG. 1 is a diagram showing a substrate processing apparatus.

FIG. 2 is a diagram showing a polishing module.

FIG. 3 is a diagram showing a cleaning module including a buff cleaning member.

FIG. 4 is a diagram showing a cleaning module including a pencil cleaning member.

FIG. 5 is a diagram showing a dressing device including a free joint structure.

FIG. 6 is a perspective view of a free joint structure.

FIG. 7 is a cross-sectional view of a free joint structure.

FIG. 8 is a diagram showing a free joint structure in a state in which a push-pull force generating portion is not applying a push-pull force to a target load portion.

FIG. 9 is a diagram showing a free joint structure in a state in which a push-pull force generating portion has applied a pull force to a target load portion.

FIG. 10 is a diagram showing a free joint structure in a state in which a push-pull force generating portion has applied a push force to a target load portion.

FIG. 11 is a diagram showing a radial gap and an axial gap of a free joint structure.

FIG. 12 is a diagram showing a free joint structure including a shim that adjusts the size of a gap.

FIG. 13 is a diagram showing another embodiment of a free joint structure.

FIG. 14 is a diagram showing another embodiment of a push-pull device.

FIG. 15 is a plan view of a fixing bracket.

FIG. 16 is a diagram showing one embodiment of a free joint structure.

FIG. 17 is a plan view of a connection plate.

### DESCRIPTION OF THE EMBODIMENTS

The disclosure provides a push-pull device and a substrate processing module, in which a piston rod can be prevented from colliding with a cylinder housing.

In one embodiment, a push-pull device is provided. The push-pull device includes a free joint structure, an air bearing cylinder connected to the free joint structure, and a fixing bracket that receives a radial load acting on a rod structure connected to the air bearing cylinder.

In one embodiment, the fixing bracket has a notch located around the rod structure.

In one embodiment, the fixing bracket is fixed to a cylinder housing that accommodates the rod structure.

In one embodiment, the free joint structure includes a pressing member connected to the rod structure, a contact member arranged facing the pressing member, and a connection block having an accommodation recess that accommodates the pressing member and the contact member.

In one embodiment, the free joint structure includes a connection plate attached to the connection block, and the connection plate closes the accommodation recess.

In one embodiment, the connection plate has a notch located around the rod structure.

In one embodiment, the free joint structure includes a push-pull force generating portion that generates a push-pull force, and a target load portion connected to the push-pull force generating portion and to which the push-pull force from the push-pull force generating portion is applied. The push-pull force generating portion is configured to apply a push force to the target load portion by point contact with the target load portion, and to apply a pull force to the target load portion by surface contact with the target load portion.

In one embodiment, the free joint structure includes an axial gap and a radial gap formed between the push-pull force generating portion and the target load portion.

In one embodiment, the free joint structure includes a shim that adjusts a size of the axial gap.

In one embodiment, the target load portion includes a pressing flat surface portion arranged facing the push-pull force generating portion, and an opening flat surface portion arranged on a side opposite the pressing flat surface portion and having an opening into which the push-pull force generating portion is inserted. The push-pull force generating portion includes a spherical portion that makes point contact with the pressing flat surface portion, and a flat surface flange portion that makes surface contact with the opening flat surface portion.

In one embodiment, the spherical portion and the flat surface flange portion are arranged on sides opposite each other.

In one embodiment, the spherical portion is arranged facing the pressing flat surface portion, and the flat surface flange portion is arranged facing the opening flat surface portion.

In one embodiment, the target load portion includes a spacer arranged between the pressing flat surface portion and the opening flat surface portion.

In one embodiment, a substrate processing module is provided. The substrate processing module includes the push-pull device described above, a shaft connected to the push-pull device, and a processing member connected to the shaft and configured to process a substrate or a polishing pad.

In one embodiment, the processing member corresponds to at least one of a polishing head that polishes the substrate and a dresser that dresses the polishing pad.

In one embodiment, the processing member corresponds to at least one of a buff cleaning member and a pencil cleaning member that clean the substrate.

According to the above means, the push-pull device is able to prevent the piston rod from colliding with the cylinder housing.

Embodiments of the present disclosure will be hereinafter described with reference to the drawings. In the drawings described below, the same or corresponding components are denoted by the same reference numerals, and repeated description will be omitted. In multiple embodiments described below, a configuration of one embodiment that is not particularly described is the same as that of other embodiments, and repeated description thereof will therefore be omitted.

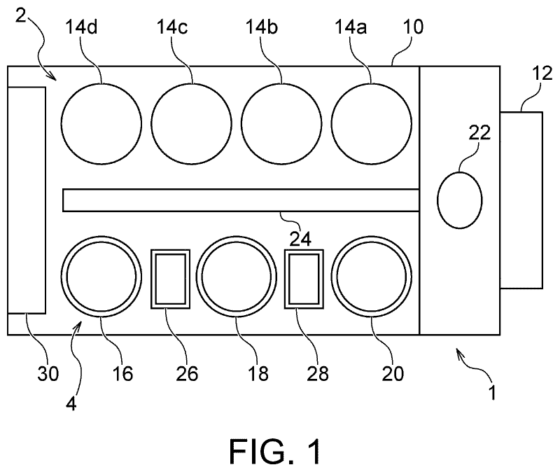

FIG. 1 is a diagram showing a substrate processing apparatus. As shown in FIG. 1, a substrate processing apparatus 1 includes a housing 10 and a load port 12 on which a substrate cassette that stocks a large number of wafers is placed. The load port 12 is arranged adjacent to the housing 10. The wafer is, for example, a semiconductor wafer, and is one example of a substrate.

The substrate processing apparatus 1 includes a polishing part 2 and a cleaning part 4 arranged inside the housing 10. The polishing part 2 includes multiple (four in the present embodiment) polishing modules 14a to 14d. The cleaning part 4 includes a first cleaning module 16 and a second cleaning module 18 that clean a polished substrate, and a drying module 20 that dries a cleaned substrate.

The polishing modules 14a to 14d are arranged along a longitudinal direction of the substrate processing apparatus 1. Similarly, the first cleaning module 16, the second cleaning module 18, and the drying module 20 are arranged along the longitudinal direction of the substrate processing apparatus 1.

In this specification, the polishing modules 14a to 14d, the first cleaning module 16, and the second cleaning module 18 are collectively referred to as a substrate processing module that processes a substrate.

The substrate processing apparatus 1 includes a first transfer robot 22 arranged adjacent to the load port 12, and a transfer module 24 arranged adjacent to the polishing modules 14a to 14d. The first transfer robot 22 receives a substrate before polishing from the load port 12 and delivers the same to the transfer module 24, and also receives a substrate after drying from the drying module 20 and returns the same to the load port 12. The transfer module 24 transfers a substrate received from the first transfer robot 22 and performs delivery of the substrate to and from each of the polishing modules 14a to 14d.

The substrate processing apparatus 1 includes a second transfer robot 26 arranged between the first cleaning module 16 and the second cleaning module 18, and a third transfer robot 28 arranged between the second cleaning module 18 and the drying module 20. The second transfer robot 26 performs delivery of a substrate between the transfer module 24 and each of the cleaning modules 16 and 18. The third transfer robot 28 performs delivery of a substrate to and from each of the modules 18 and 20.

The substrate processing apparatus 1 includes a control device 30 arranged inside the housing 10. The control device 30 is configured to control movement of each device of the substrate processing module.

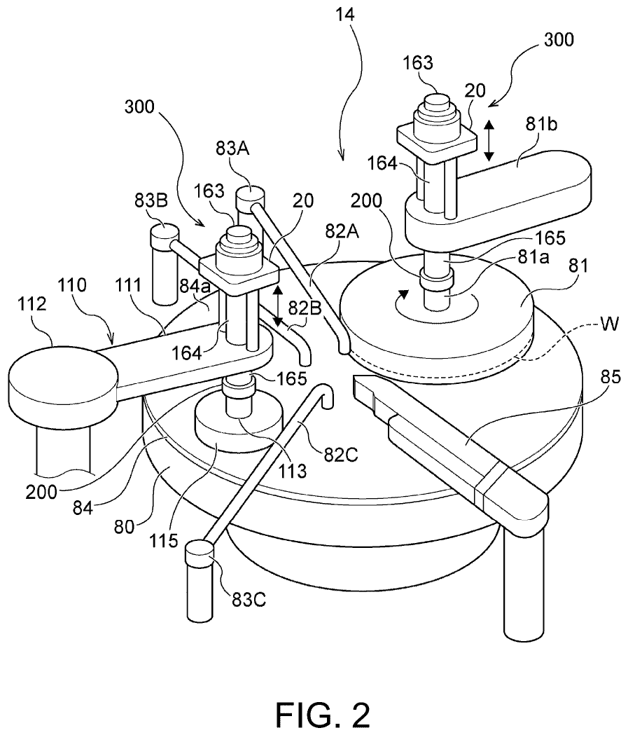

FIG. 2 is a diagram showing a polishing module. In the embodiment described below, the polishing modules 14a to 14d may be collectively referred to as polishing module 14. The polishing module 14 includes a polishing table 80 that supports a polishing pad 84 having a polishing surface 84a, a polishing head (top ring) 81 that holds a wafer W and presses the same against the polishing surface 84a, and a slurry supply nozzle 82A that supplies slurry (polishing liquid) to the polishing surface 84a.

The polishing module 14 includes a pure water supply nozzle 82B that supplies pure water to the polishing surface 84a, a chemical supply nozzle 82C that supplies a chemical to the polishing surface 84a, and a pure water supply nozzle 85 that supplies pure water for removing slurry adhering to the polishing surface 84a. In other words, the pure water supply nozzle 85 is an atomizer. Accordingly, the pure water supply nozzle 85 may be hereinafter referred to as atomizer 85.

In the embodiment shown in FIG. 2, the polishing module 14 includes multiple supply nozzles 82A, 82B, and 82C. However, in one embodiment, the polishing module 14 may include, instead of the multiple supply nozzles 82A, 82B, and 82C, a single supply nozzle that selectively supplies any liquid among slurry, pure water, and a chemical.

The polishing module 14 includes a dressing device 110 for dressing the polishing pad 84. The dressing device 110 includes a dresser 115 in sliding contact with the polishing surface 84a of the polishing pad 84, a shaft 113 connected to the dresser 115, a dresser arm 111 that supports the dresser 115 via the shaft 113, and a dresser pivot shaft 112 that pivots the dresser arm 111. The dresser pivot shaft 112 is arranged outside the polishing pad 84.

As the dresser arm 111 pivots, the dresser 115 oscillates on the polishing surface 84a. A lower surface of the dresser 115 constitutes a dressing surface composed of a large number of abrasive grains such as diamond particles.

The polishing module 14 includes an air bearing cylinder 163 mounted on the dressing device 110. The air bearing cylinder 163 (more specifically, a piston rod 165) is connected to the shaft 113 via a free joint structure 200 described later.

The dresser 115 (and the shaft 113) is configured to be movable in an up-down direction by the air bearing cylinder 163. The air bearing cylinder 163 is configured to be driven to thereby adjust a distance between the dresser 115 and the polishing pad 84.

In the dressing device 110 having such a configuration, the dresser 115 is operated so as to rotate while oscillating on the polishing surface 84a, and the polishing pad 84 is slightly scraped off by the dresser 115, thereby dressing the polishing surface 84a.

The polishing table 80 is formed in a disk shape and is configured to be rotatable about its central axis as a rotation axis. The polishing pad 84 is attached to an upper surface of the polishing table 80. When the polishing table 80 is rotated by a motor (not shown), the polishing pad 84 rotates integrally with the polishing table 80.

The top ring 81 holds the wafer W on its lower surface by vacuum suction or the like. The top ring 81 is configured to be rotatable together with the wafer W by power from a motor (not shown).

The top ring 81 is connected to a shaft 81a. The shaft 81a is connected to the air bearing cylinder 163 (more specifically, the piston rod 165) via the free joint structure 200. The top ring 81 is configured to be movable in the up-down direction by the air bearing cylinder 163.

The air bearing cylinder 163 is configured to be driven to thereby adjust a distance between the top ring 81 and the polishing table 80. By such a configuration, the top ring 81 presses the wafer W held by the top ring 81 itself against the polishing surface 84a of the polishing pad 84.

A support arm 81b that supports the top ring 81 is configured to be oscillatable by a motor (not shown), and moves the top ring 81 in a direction parallel to the polishing surface 84a. In the present embodiment, the top ring 81 is configured to be movable between a position where the top ring 81 receives the wafer W (not shown) and a position above the polishing pad 84, and a position where the wafer W is pressed against the polishing pad 84 can be changed.

The slurry supply nozzle 82A is provided above the polishing table 80 and supplies slurry onto the polishing pad 84. The slurry supply nozzle 82A is supported by a shaft 83A. The shaft 83A is configured to be movable by a motor (not shown). Accordingly, the slurry supply nozzle 82A can change a dropping position of slurry about the shaft 83A during polishing processing of the wafer W. In this way, the slurry supply nozzle 82A supplies slurry so as to infiltrate a contact interface between the rotating wafer W and the polishing pad 84.

The pure water supply nozzle 82B is provided above the polishing table 80 and supplies pure water onto the polishing pad 84. The pure water supply nozzle 82B is supported by a shaft 83B. Similarly, the chemical supply nozzle 82C is provided above the polishing table 80 and supplies a chemical onto the polishing pad 84. The chemical supply nozzle 82C is supported by a shaft 83C. Each of these shafts 83B and 83C is configured to be movable by a motor (not shown).

The atomizer 85 is provided above the polishing table 80 and extends along a radial direction of the polishing table 80. The atomizer 85 injects a cleaning fluid at a predetermined flow rate toward the polishing pad 84 immediately after a polishing process of the wafer W using slurry, and washes away a portion of the slurry adhering to the polishing surface 84a and the wafer W. The cleaning fluid is composed of a mixed fluid of a liquid (usually pure water) and a gas (for example, inert gas such as nitrogen gas).

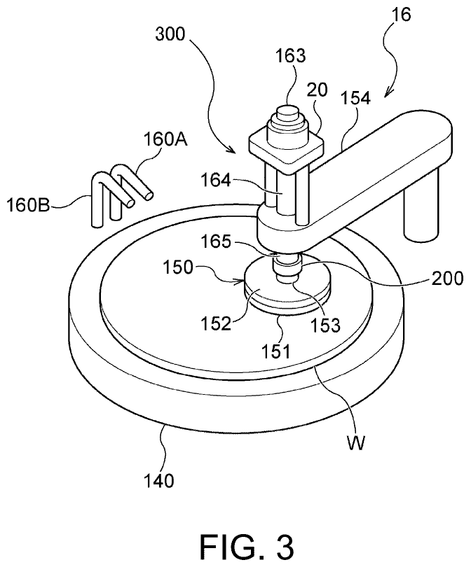

FIG. 3 is a diagram showing a cleaning module including a buff cleaning member. As shown in FIG. 3, the cleaning module 16 (or the cleaning module 18) includes a buff cleaning member 150 that cleans the wafer W while contacting a surface of the wafer W, and a rotational table 140 that supports the wafer W.

The buff cleaning member 150 includes a buff pad 151 that buff-cleans the wafer W, and a buff head 152 that holds the buff pad 151. The buff head 152 is connected to a shaft 153.

The shaft 153 is connected to the air bearing cylinder 163 (more specifically, the piston rod 165) via the free joint structure 200. The buff cleaning member 150 is configured to be movable in the up-down direction by the air bearing cylinder 163.

The air bearing cylinder 163 is configured to be driven to thereby adjust a distance between the buff cleaning member 150 and the wafer W supported by the rotational table 140. The buff head 152 is configured to bring the buff pad 151 into contact with the wafer W while rotating the buff pad 151.

In the embodiment shown in FIG. 3, the cleaning module 16 (or the cleaning module 18) includes a pure water supply nozzle 160A for supplying pure water to the surface of the wafer W, and a chemical supply nozzle 160B for supplying a chemical to the surface of the wafer W.

A buff arm 154 that supports the buff cleaning member 150 is configured to oscillate the buff cleaning member 150. When the buff arm 154 oscillates the buff head 151 while the rotational table 140 rotates the wafer W, the wafer W is cleaned as a whole.

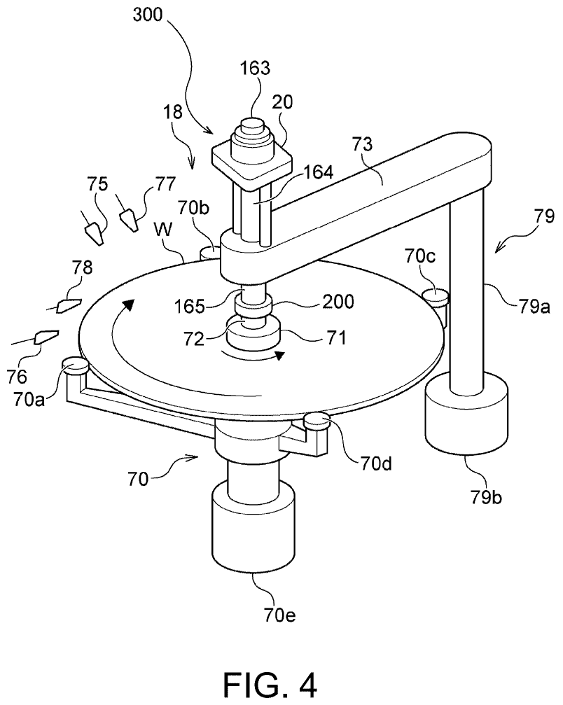

FIG. 4 is a diagram showing a cleaning module including a pencil cleaning member. As shown in FIG. 4, the cleaning module 18 (or the cleaning module 16) includes a substrate holding mechanism 70 that holds and rotates the wafer W, and a cleaning member 71 that contacts the wafer W and subjects the wafer W to scrubbing processing.

The cleaning member 71 is connected to a shaft 72. The shaft 72 is connected to the air bearing cylinder 163 (more specifically, the piston rod 165) via the free joint structure 200. The cleaning member 71 is configured to be movable in the up-down direction by the air bearing cylinder 163. The air bearing cylinder 163 is configured to be driven to thereby adjust a distance between the cleaning member 71 and the wafer W held by the substrate holding mechanism 70. The air bearing cylinder 163 presses, with a predetermined pressure, the cleaning member 71 against the surface of the wafer W. The cleaning member 71 pressed against the surface of the wafer W scrubs (scrub cleans) the wafer W.

The cleaning module 18 (or the cleaning module 16) includes an arm oscillation mechanism 79 that horizontally oscillates an arm 73 supporting the cleaning member 71, chemical supply nozzles 75 and 76 that supply a processing liquid (diluted chemical in the present embodiment) toward a front surface and back surface of the wafer W, and pure water supply nozzles 77 and 78 that supply pure water toward the front surface and back surface of the wafer W.

The substrate holding mechanism 70 includes chucks 70a to 70d that hold a peripheral portion of the wafer W, and a motor 70e connected to the chucks 70a to 70d. The chucks 70a to 70d hold the wafer W and drive the motor 70e, thereby causing the wafer W to rotate about its axis.

The cleaning member 71 is a sponge member that has a pencil shape, contacts the surface of the wafer W while rotating around a central axis of the cleaning member 71, and scrubs the wafer W. The cleaning member 71 may be hereinafter referred to as pencil cleaning member 71.

The arm 73 is arranged above the wafer W and is connected to the arm oscillation mechanism 79. The arm oscillation mechanism 79 includes a pivot shaft 79a and a rotation mechanism 79b. One end of the arm 73 is connected to the pivot shaft 79a, and the pencil cleaning member 71 is connected to the other end of the arm 73. A direction of the central axis of the pencil cleaning member 71 is perpendicular to the front surface (or back surface) of the wafer W.

The rotation mechanism 79b that pivots the arm 73 is connected to the pivot shaft 79a. The rotation mechanism 79b is configured to pivot the arm 73 in a plane parallel to the wafer W by rotating the pivot shaft 79a.

As described above, the substrate processing module (that is, the polishing module 14, the first cleaning module 16, and the second cleaning module 18) includes the air bearing cylinder 163 that operates a processing member that processes the wafer W or the polishing pad 84. Examples of the processing member that processes the wafer W include the top ring 81, the buff cleaning member 150, and the pencil cleaning member 71. Examples of the processing member that processes the polishing pad 84 include the dresser 115.

The air bearing cylinder 163 has a configuration that supports the piston rod 165 in a non-contact manner by a compressed gas supplied into a cylinder housing 164. Accordingly, unlike a general air cylinder, the air bearing cylinder 163 is able to prevent sliding friction occurring between the piston rod 165 and the cylinder housing 164.

On the other hand, the air bearing cylinder 163 has low radial rigidity. Accordingly, if a deviation (that is, eccentricity or declination) occurs between the piston rod 165 and the shaft 113 (and/or the shafts 81a, 153, and 72), there is a risk that the piston rod 165 may contact the cylinder housing 164 during a movement of the piston rod 165 due to the deviation.

Accordingly, the substrate processing module includes the free joint structure 200 that is able to absorb the deviation between a piston rod and a shaft. A structure of the free joint structure 200 will be hereinafter described with reference to the drawings.

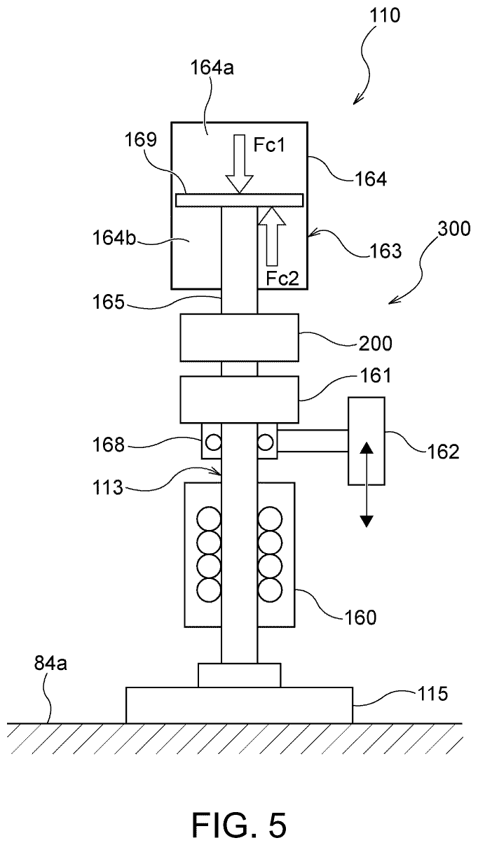

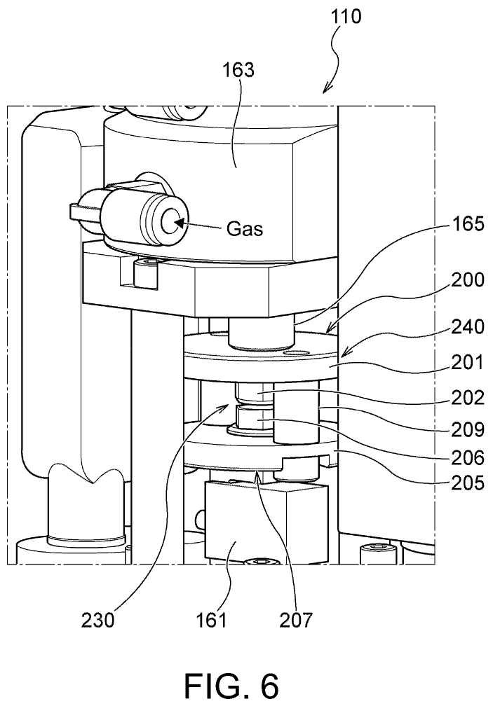

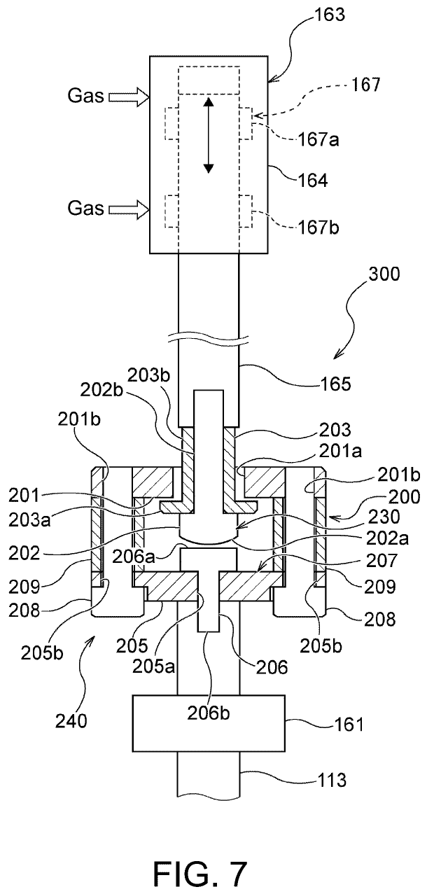

FIG. 5 is a diagram showing a dressing device including a free joint structure. FIG. 6 is a perspective view of a free joint structure. FIG. 7 is a cross-sectional view of a free joint structure. In the embodiment shown in FIG. 5 to FIG. 7, the free joint structure 200 connected to the shaft 113 of the dressing device 110 will be described. However, the free joint structure 200 is not limited to being connected to the shaft 113 of the dressing device 110, and may be connected to at least one of the shaft 81a to which the top ring 81 is connected, the shaft 153 to which the buff cleaning member 150 is connected, and the shaft 72 to which the pencil cleaning member 71 is connected (see FIG. 2, FIG. 3, and FIG. 4).

As shown in FIG. 5, the dressing device 110 includes a guide member 160 that guides the shaft 113, a bearing 168 that rotatably supports the shaft 113, a pad height measuring device (for example, a displacement sensor) 162 attached to the bearing 168, and a load measuring device (for example, a load cell) 161 that measures a load of the dresser 115 applied to the polishing pad 84.

The pad height measuring device 162 is configured to measure a distance between the pad height measuring device 162 and the polishing surface 84a of the polishing pad 84. The control device 30 is electrically connected to the pad height measuring device 162 and the load measuring device 161. Accordingly, the control device 30 accurately controls dressing of the polishing pad 84 based on a measured value sent from the pad height measuring device 162 and the load measuring device 161.

The air bearing cylinder 163 includes the piston rod 165 connected to the shaft 113 via the free joint structure 200, and the cylinder housing 164 that accommodates the piston rod 165.

A combination of the air bearing cylinder 163 and the free joint structure 200 constitutes a push-pull device 300. The control device 30 is electrically connected to the push-pull device 300 and is configured to control an operation of the push-pull device 300.

The cylinder housing 164 has a partition wall 169 arranged therein. The partition wall 169 divides an internal space of the cylinder housing 164 into a first space 164a and a second space 164b.

As shown in FIG. 5, by supplying a compressed gas to the first space 164a, the compressed gas generates a push force Fc1 on the partition wall 169. By supplying a compressed gas to the second space 164b, the compressed gas generates a pull force Fc2 on the partition wall 169. The piston rod 165 moves forward by the push force Fc1 and moves backward by the pull force Fc2.

As shown in FIG. 7, the cylinder housing 164 includes an annular gas accommodation chamber 167 (more specifically, a first gas accommodation chamber 167a and a second gas accommodation chamber 167b) arranged around the piston rod 165. As shown in FIG. 6 and FIG. 7, by supplying a compressed gas to the gas accommodation chamber 167, in the cylinder housing 164, a compressed gas layer is formed in the gas accommodation chamber 167. The compressed gas layer supports the piston rod 165 in a non-contact manner. In FIG. 7, illustration of the first space 164a, the second space 164b, and the partition wall 169 shown in FIG. 5 is omitted.

As shown in FIG. 7, the free joint structure 200 includes a push-pull force generating portion 230 that generates a push-pull force as the piston rod 165 moves, and a target load portion 240 connected to the push-pull force generating portion 230 and to which the push-pull force from the push-pull force generating portion 230 is applied.

The push-pull force generating portion 230 is configured to apply the push force Fc1 to the target load portion 240 by point contact with the target load portion 240, and to apply the pull force Fc2 to the target load portion 240 by surface contact with the target load portion 240.

More specifically, the push-pull force generating portion 230 includes a pressing member 202 connected to the piston rod 165, and a pull-up member 203 fixed to the pressing member 202. The target load portion 240 includes a pressing flat surface portion 207 arranged facing the push-pull force generating portion 230, and an opening flat surface portion 201 arranged on a side opposite the pressing flat surface portion 207 and having an opening 201a into which the push-pull force generating portion 230 is inserted.

The pressing member 202 of the push-pull force generating portion 230 includes a spherical portion 202a that makes point contact with the pressing flat surface portion 207, and a rod portion 202b fixed to the spherical portion 202a. The rod portion 202b is fixed to the piston rod 165, and the spherical portion 202a is arranged at a tip of the rod portion 202b. The piston rod 165 and the rod portion 202b extend on a straight line.

The pull-up member 203 includes a cylindrical portion 203b into which the rod portion 202b is inserted, and a flat surface flange portion 203a extending radially outward from the cylindrical portion 203b. The push-pull force generating portion 230 (more specifically, the rod portion 202b and the cylindrical portion 203b) is inserted into the opening 201a formed in the center of the opening flat surface portion 201. The spherical portion 202a and the flat surface flange portion 203a are arranged below the opening flat surface portion 201, and are arranged on sides opposite each other.

The spherical portion 202a is arranged facing the pressing flat surface portion 207 so as to be capable of point contact with the pressing flat surface portion 207. The flat surface flange portion 203a is arranged facing the opening flat surface portion 201 so as to be capable of surface contact with the opening flat surface portion 201.

In the present embodiment, the pressing flat surface portion 207 is arranged below the push-pull force generating portion 230. More specifically, the pressing flat surface portion 207 includes a contact member 206 arranged facing the spherical portion 202a, and a support flange 205 that supports the contact member 206.

The contact member 206 includes a contact portion 206a that contacts the spherical portion 202a of the pressing member 202, and a rod portion 206b fixed to the contact portion 206a. The contact portion 206a has a machined surface formed on its surface.

The rod portion 206b is connected to the shaft 113 and extends on a straight line with the rod portion 202b. The support flange 205 has an opening 205a formed in its center. The rod portion 206b passes through the opening 205a of the support flange 205.

In the present embodiment, the spherical portion 202a is formed in the pressing member 202, and the contact portion 206a is formed in the contact member 206. However, the structure of the free joint structure 200 is not particularly limited if the pressing member 202 can be brought into point contact with the contact member 206. In one embodiment, the pressing member 202 may include a contact portion corresponding to the contact portion 206a, and the contact member 206 may include a spherical portion corresponding to the spherical portion 202a.

The pressing flat surface portion 207 and the opening flat surface portion 201 are arranged parallel to each other. The target load portion 240 includes multiple spacers 209 arranged between the pressing flat surface portion 207 and the opening flat surface portion 201, and a fastener 208 that fastens the pressing flat surface portion 207 and the opening flat surface portion 201, includes.

The opening flat surface portion 201 has multiple fastening holes 201b arranged around the opening 201a. The support flange 205 has multiple insertion holes 205b arranged around the opening 205a. The spacer 209 has a cylindrical shape through which the fastener 208 passes.

The fastener 208 is inserted into the insertion hole 205b and the fastening hole 201b through the spacer 209. In this state, by tightening the fastener 208, the fastener 208 fixes relative positions of the pressing flat surface portion 207 and the opening flat surface portion 201.

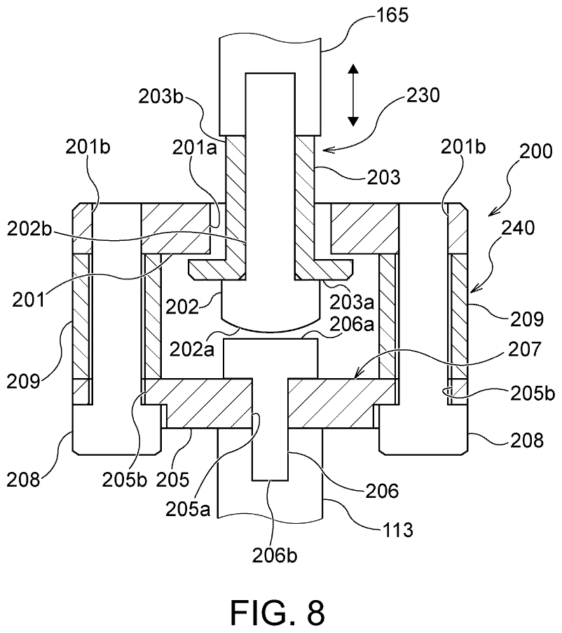

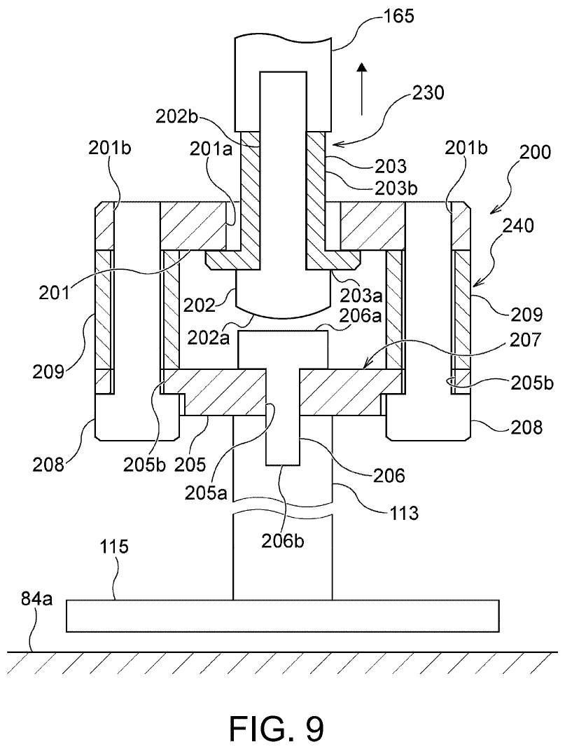

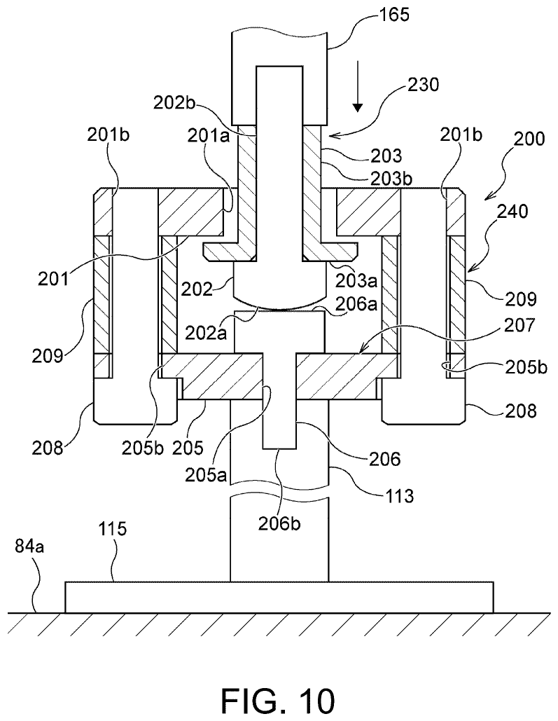

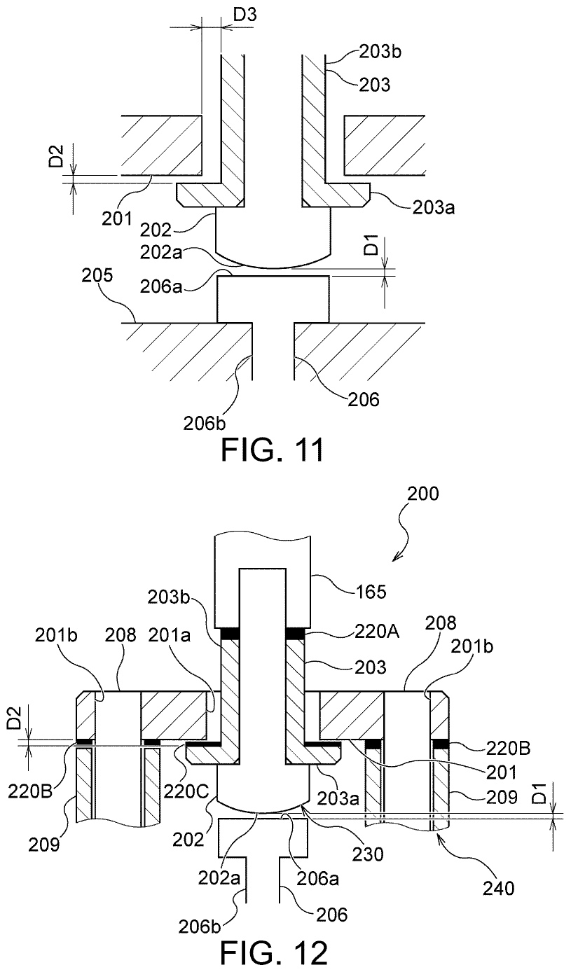

FIG. 8 is a diagram showing a free joint structure in a state in which a push-pull force generating portion is not applying a push-pull force to a target load portion. FIG. 9 is a diagram showing a free joint structure in a state in which a push-pull force generating portion has applied a pull force to a target load portion. FIG. 10 is a diagram showing a free joint structure in a state in which a push-pull force generating portion has applied a push force to a target load portion. FIG. 11 is a diagram showing a radial gap and an axial gap of a free joint structure.

As shown in FIG. 11, the free joint structure 200 includes axial gaps D1 and D2 and a radial gap D3 formed between the push-pull force generating portion 230 and the target load portion 240. In one embodiment, each of the axial gaps D1 and D2 has a size of 0.1 mm. For example, when the spherical portion 202a is brought into point contact with the contact portion 206 a (that is, when the axial gap D1 is zero), the axial gap D2 is 0.2 mm.

Similarly, when the flat surface flange portion 203a is brought into surface contact with the opening flat surface portion 201 (that is, when the axial gap D2 is zero), the axial gap D1 is 0.2 mm. In one embodiment, the radial gap D3 is 2.0 mm.

In one embodiment, from the viewpoint of push-pull control responsiveness or required deviation tolerance, the size of each of the axial gaps D1 and D2 may be set in a range of 0.01 to 0.2 mm, and the radial gap D3 may be set in a range of 0.5 to 2 mm.

As shown in FIG. 8, in the case where no push-pull force from the push-pull force generating portion 230 is applied to the target load portion 240, the push-pull force generating portion 230 is fixed to the piston rod 165 in a state in which the axial gaps D1 and D2 and the radial gap D3 are formed. In other words, the push-pull force generating portion 230 is in a free state with respect to the target load portion 240.

As shown in FIG. 9, when a compressed gas is supplied to the second space 164b to raise the push-pull force generating portion 230, the flat surface flange portion 203a of the pull-up member 203 comes into surface contact with the opening flat surface portion 201. In this way, the push-pull force generating portion 230 applies the pull force Fc2 to the target load portion 240. As a result, the push-pull force generating portion 230 separates the dresser 115 together with the shaft 113 from the polishing pad 84 via the target load portion 240.

As shown in FIG. 10, when a compressed gas is supplied to the first space 164a to lower the push-pull force generating portion 230, the spherical portion 202a of the pressing member 202 comes into point contact with the contact portion 206a of the contact member 206. In this way, the push-pull force generating portion 230 applies the push force Fc1 to the target load portion 240. As a result, the push-pull force generating portion 230 brings the dresser 115 together with the shaft 113 close to the polishing pad 84 via the target load portion 240.

According to the present embodiment, the free joint structure 200 is able to absorb deviation between the piston rod 165 and the shaft 113. More specifically, when the push-pull force generating portion 230 is brought into point contact with the target load portion 240, the axial gaps D1 and D2 and the radial gap D3 allow deviation (declination) between the piston rod 165 and the shaft 113.

Accordingly, even in the case where deviation (declination) occurs between the piston rod 165 and the shaft 113, the piston rod 165 is able to move forward and move backward without being affected by the declination. As a result, the free joint structure 200 is able to prevent the piston rod 165 from sliding against the cylinder housing 164.

When the push-pull force generating portion 230 is brought into surface contact with the target load portion 240, the axial gaps D1 and D2 and the radial gap D3 allow deviation (eccentricity) between the piston rod 165 and the shaft 113. Accordingly, even in the case where deviation (eccentricity) occurs between the piston rod 165 and the shaft 113, the piston rod 165 is able to move forward and move backward without being affected by the eccentricity. As a result, the free joint structure 200 is able to prevent the piston rod 165 from sliding against the cylinder housing 164.

In the case where a design error occurs in the flat surface flange portion 203a that comes into surface contact with the target load portion 240, that is, in the case where the flat surface flange portion 203a does not have a completely flat surface, there is a risk that the push-pull force generating portion 230 is not able to reliably absorb the eccentricity. A similar problem may occur in the opening flat surface portion 201 of the target load portion 240 with which the flat surface flange portion 203a comes into surface contact.

Accordingly, it is desirable that the contact area of the flat surface flange portion 203a with the target load portion 240 is as small as possible. In one embodiment, an outer diameter of the flat surface flange portion 203a is 1.5 times a diameter of the rod portion 202b.

FIG. 12 is a diagram showing a free joint structure including a shim that adjusts the size of a gap. As shown in FIG. 12, the free joint structure 200 may include shims 220A, 220B, and 220C that adjust the size of the gaps. By arranging at least one of the shims 220A, 220B, and 220C according to a design error of the push-pull force generating portion 230 and the target load portion 240 or required precision, the size of the gaps of the free joint structure 200 can be adjusted.

In the embodiment shown in FIG. 12, the shim 220A is arranged between the cylindrical portion 203b of the pull-up member 203 and the piston rod 165. By arranging the shim 220A, the size of the axial gap D2 between the flat surface flange portion 203a of the pull-up member 203 and the opening flat surface portion 201 can be adjusted.

The shim 220B is arranged between the spacer 209 and the opening flat surface portion 201. By arranging the shim 220B, the size of the axial gap D1 between the spherical portion 202a of the pressing member 202 and the contact portion 206a of the contact member 206 can be adjusted.

The shim 220C is arranged between the flat surface flange portion 203a of the pull-up member 203 and the opening flat surface portion 201. By arranging the shim 220C, the size of the axial gap D2 between the flat surface flange portion 203a and the opening flat surface portion 201 can be adjusted.

In this way, the free joint structure 200 may include the shim 220A (and/or the shim 220C) that adjusts the size of the axial gap D2, and may include the shim 220B that adjusts the size of the axial gap D1.

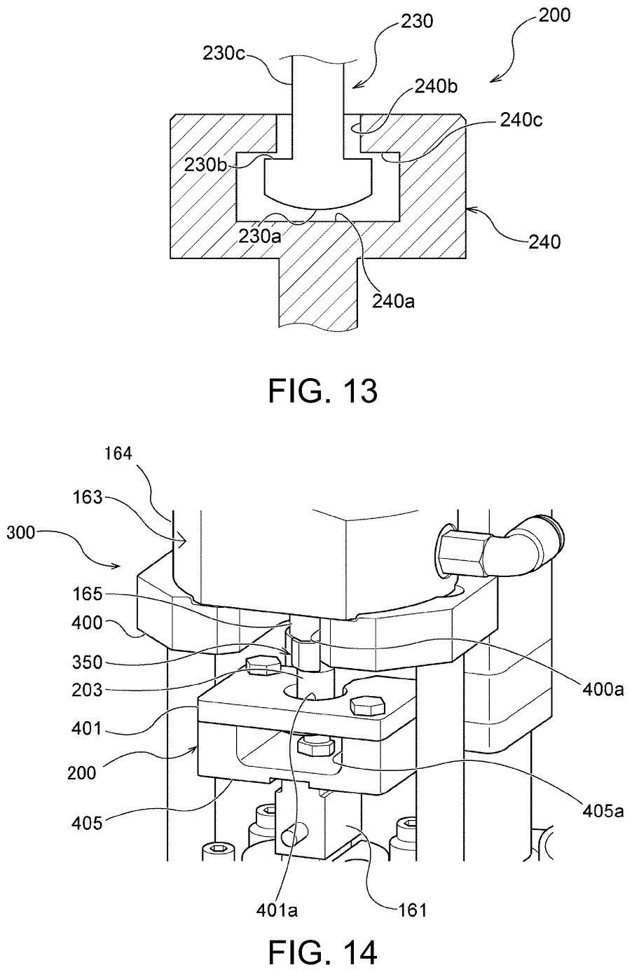

FIG. 13 is a diagram showing another embodiment of a free joint structure. As shown in FIG. 13, the free joint structure 200 may include the push-pull force generating portion 230 in which the pressing member 202 and the pull-up member 203 described with reference to the above-described embodiment are integrally configured, and the target load portion 240 in which the opening flat surface portion 201, the pressing flat surface portion 207, and the spacer 209 are integrally configured.

In the embodiment shown in FIG. 13, the target load portion 240 includes a pressing flat surface portion 240a arranged facing the push-pull force generating portion 230, and an opening flat surface portion 240c having an opening 240b into which the push-pull force generating portion 230 is inserted. The push-pull force generating portion 230 includes a spherical portion 230a that makes point contact with the pressing flat surface portion 240a, and a flat surface flange portion 230b that makes surface contact with the opening flat surface portion 240c.

According to the present embodiment, in the free joint structure 200, a simple structure can be provided and the number of parts can be reduced. In the present embodiment as well, in the free joint structure 200, the same effects as those of the free joint structure 200 according to the above-described embodiment can be achieved.

In the above-described embodiment, the substrate processing module (more specifically, the polishing module 14) includes the push-pull device 300 composed of a combination of the air bearing cylinder 163 and the free joint structure 200, the shaft 113 connected to the push-pull device 300, and the dresser 115 as a processing member connected to the shaft 113 (see, for example, FIG. 5).

In one embodiment, the substrate processing module (more specifically, the polishing module 14) may include the push-pull device 300, the shaft 81a connected to the push-pull device 300, and the top ring (that is, the polishing head) 81 as a processing member connected to the shaft 81a (see FIG. 2).

In one embodiment, the substrate processing module (the cleaning module 16 or 18) may include the push-pull device 300, the shaft 153 connected to the push-pull device 300, and the buff cleaning member 150 as a processing member connected to the shaft 153 (see FIG. 3).

In one embodiment, the substrate processing module (the cleaning module 16 or 18) may include the push-pull device 300, the shaft 72 connected to the push-pull device 300, and the pencil cleaning member 71 as a processing member connected to the shaft 72 (see FIG. 4).

During assembly of the push-pull device 300 or during driving of the push-pull device 300, there are cases where a radial load (that is, a lateral load) may act on the piston rod 165. In this case, there is a risk that the piston rod 165 may collide with the cylinder housing 164. When the piston rod 165 collides with the cylinder housing 164, damage may occur to the piston rod 165 and/or the cylinder housing 164.

Such damage may cause malfunction of the push-pull device 300, and there is a risk that an operation of the piston rod 165 may be hindered. As a result, there is a possibility that the substrate processing module may issue an alarm or stop an operation of the push-pull device 300.

Accordingly, the push-pull device 300 has a configuration that prevents the piston rod 165 from colliding with the cylinder housing 164. Such a configuration will be hereinafter described with reference to the drawings. In this specification, the piston rod 165 and the pull-up member 203 may be collectively referred to as rod structure 350.

FIG. 14 is a diagram showing another embodiment of a push-pull device. As shown in FIG. 14, the push-pull device 300 includes the free joint structure 200, the air bearing cylinder 163, and a fixing bracket 400 that receives a radial load acting on the rod structure 350 connected to the air bearing cylinder 163.

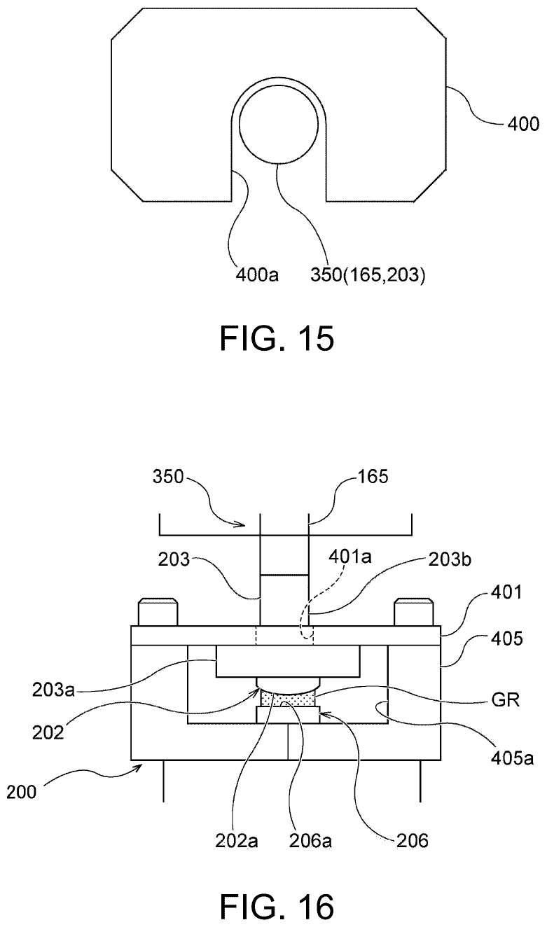

FIG. 15 is a plan view of a fixing bracket. The fixing bracket 400 is fixed to a lower surface of the cylinder housing 164 accommodating the rod structure 350 (specifically, the piston rod 165). The fixing bracket 400 has a U-shaped notch 400a extending from an outer surface toward a central portion of the fixing bracket 400.

The notch 400a has a size larger than a diameter of the rod structure 350. Accordingly, when the fixing bracket 400 is fixed to the cylinder housing 164, the notch 400a is located around the rod structure 350.

When the push-pull device 300 is assembled, it is necessary to connect the piston rod 165 and the pressing member 202 (and the pull-up member 203). If the fixing bracket 400 is not provided, during assembly work of the rod structure 350 like this, a radial load may act on the piston rod 165, and there is a risk that the piston rod 165 and/or the cylinder housing 164 may be damaged. For example, during assembly of the push-pull device 300, if the piston rod 165 in an inclined state is inserted into the cylinder housing 164, there is a risk that the piston rod 165 and/or the cylinder housing 164 may be damaged.

According to the present embodiment, the fixing bracket 400 is able to receive a radial load acting on the piston rod 165. In other words, the fixing bracket 400 is able to guide the piston rod 165 to move parallel to the cylinder housing 164. Accordingly, the fixing bracket 400 is able to prevent the piston rod 165 from colliding with the cylinder housing 164. As a result, damage to the piston rod 165 and/or the cylinder housing 164 can be prevented.

In this way, by providing the fixing bracket 400, assemblability of the push-pull device 300 by an operator can be improved. Furthermore, by forming the notch 400a in the fixing bracket 400, the fixing bracket 400 is fixed to the cylinder housing 164 so as to avoid the piston rod 165, in other words, without contacting the piston rod 165.

By such a configuration, it is not necessary to fix the fixing bracket 400 to the cylinder housing 164 in advance, and the fixing bracket 400 can be fixed to the cylinder housing 164 during assembly work of the rod structure 350.

Accordingly, it is possible for the operator to perform other assembly work first, and to, after completion of the other assembly work, fix the fixing bracket 400 to the cylinder housing 164 during assembly work of the rod structure 350. As a result, assemblability of the push-pull device 300 can be further improved.

In the embodiment shown in FIG. 14, the push-pull device 300 includes the free joint structure 200 including the push-pull force generating portion 230 and the target load portion 240, and the fixing bracket 400. However, the push-pull device 300 does not have to include a combination of the free joint structure 200 having such a configuration and the fixing bracket 400.

That is, the free joint structure 200 does not necessarily have to include the push-pull force generating portion 230 and the target load portion 240. The fixing bracket 400 is generally applicable to devices for preventing the piston rod 165 from colliding with the cylinder housing 164.

FIG. 16 is a diagram showing one embodiment of a free joint structure. As shown in FIG. 16 (and FIG. 14), the free joint structure 200 includes the pressing member 202 connected to the rod structure 350, the contact member 206 arranged facing the pressing member 202, and a connection block 405 having an accommodation recess 405a accommodating the pressing member 202 and the contact member 206.

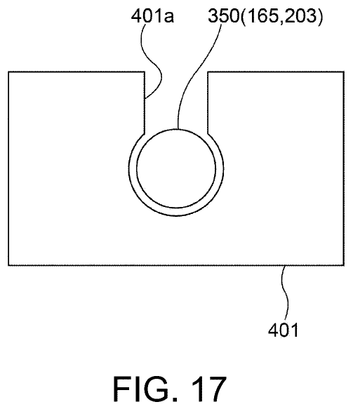

FIG. 17 is a plan view of a connection plate. The free joint structure 200 includes a connection plate 401 attached to the connection block 405. The connection plate 401 functions as a guide member that guides a movement of the piston rod 165, similarly to the fixing bracket 400. The connection plate 401 has a notch 401a located around the rod structure 350 (specifically, the pull-up member 203). An upper surface of the connection block 405 is connected to the connection plate 401 (see FIG. 16).

By forming the notch 401a in the connection plate 401, the connection plate 401 can be connected to the connection block 405 after completion of assembly work of the rod structure 350. As a result, assemblability of the push-pull device 300 can be improved. Furthermore, since the push-pull device 300 can be assembled by such a simple method, mechanical errors between devices caused by assembly work can be minimized.

The connection block 405 having the accommodation recess 405a has a U-shaped cross-sectional shape. By such a structure, the connection block 405 is able to suppress scattering of wear debris generated by contact of the pressing member 202 with the contact member 206.

By connecting the connection plate 401 to the connection block 405, the connection plate 401 closes the accommodation recess 405a. By closing the accommodation recess 405a, a combination of the connection block 405 and the connection plate 401 constitutes a hollow box shape when viewed from a side.

As shown in FIG. 16, the free joint structure 200 includes grease GR arranged between the pressing member 202 and the contact member 206. For example, the grease GR is a lubricating oil having high viscosity. The grease GR is not only able to suppress scattering of wear debris but also able to suppress a radial load generated in the rod structure 350.

The dresser 115 is configured to oscillate on the polishing surface 84a as the dresser arm 111 pivots (see, for example, FIG. 2). At this time, a radial load acting on the dresser 115 acts on the contact member 206. When such a radial load acts on the rod structure 350 through the pressing member 202, there is a risk that the piston rod 165 and/or the cylinder housing 164 may be damaged. Accordingly, it is desirable that a radial load acting on the contact member 206 be not transmitted to the rod structure 350 as much as possible.

According to the present embodiment, by applying the grease GR, the grease GR is able to reduce frictional force generated between the pressing member 202 and the contact member 206. As a result, transmission of a radial load acting on the contact member 206 to the pressing member 202 can be prevented. By such a configuration, damage to the piston rod 165 and/or the cylinder housing 164 can be prevented.

The embodiments described above are described for the purpose of enabling those having ordinary skills in the art to which the present disclosure belongs to implement the present disclosure. Various modifications of the above embodiments can naturally be made by those skilled in the art, and the technical concept of the present disclosure can be applied to other embodiments. Accordingly, the present disclosure is not limited to the described embodiments, but is to be interpreted in the broadest scope according to the technical concept defined by the claims.

What is claimed is:

1. A push-pull device comprising:
a free joint structure;
an air bearing cylinder, connected to the free joint structure; and
a fixing bracket, receiving a radial load acting on a rod structure connected to the air bearing cylinder.

2. The push-pull device according to claim 1, wherein
the fixing bracket comprises a notch located around the rod structure.

3. The push-pull device according to claim 1, wherein
the fixing bracket is fixed to a cylinder housing that accommodates the rod structure.

4. The push-pull device according to claim 1, wherein
the free joint structure comprises:
a pressing member, connected to the rod structure;
a contact member, arranged facing the pressing member; and
a connection block, comprising an accommodation recess that accommodates the pressing member and the contact member.

5. The push-pull device according to claim 4, wherein
the free joint structure comprises a connection plate attached to the connection block; and
the connection plate closes the accommodation recess.

6. The push-pull device according to claim 5, wherein
the connection plate comprises a notch located around the rod structure.

7. The push-pull device according to claim 1, wherein
the free joint structure comprises:
a push-pull force generating portion, generating a push-pull force; and
a target load portion, connected to the push-pull force generating portion and to which the push-pull force from the push-pull force generating portion is applied,
wherein the push-pull force generating portion is configured to apply a push force to the target load portion by point contact with the target load portion, and to apply a pull force to the target load portion by surface contact with the target load portion.

8. The push-pull device according to claim 7, wherein
the free joint structure comprises an axial gap and a radial gap formed between the push-pull force generating portion and the target load portion.

9. The push-pull device according to claim 8, wherein
the free joint structure comprises a shim that adjusts a size of the axial gap.

10. The push-pull device according to claim 7, wherein
the target load portion comprises:
a pressing flat surface portion, arranged facing the push-pull force generating portion; and
an opening flat surface portion, arranged on a side opposite the pressing flat surface portion and having an opening into which the push-pull force generating portion is inserted, and
the push-pull force generating portion comprises:
a spherical portion, making point contact with the pressing flat surface portion; and
a flat surface flange portion, making surface contact with the opening flat surface portion.

11. The push-pull device according to claim 10, wherein
the spherical portion and the flat surface flange portion are arranged on sides opposite each other.

12. The push-pull device according to claim 10, wherein
the spherical portion is arranged facing the pressing flat surface portion; and
the flat surface flange portion is arranged facing the opening flat surface portion.

13. The push-pull device according to claim 10, wherein
the target load portion comprises a spacer arranged between the pressing flat surface portion and the opening flat surface portion.

14. A substrate processing module comprising:
the push-pull device according to claim 1;
a shaft, connected to the push-pull device; and
a processing member, connected to the shaft and configured to process a substrate or a polishing pad.

15. The substrate processing module according to claim 14, wherein
the processing member corresponds to at least one of a polishing head that polishes the substrate and a dresser that dresses the polishing pad.

16. The substrate processing module according to claim 14, wherein
the processing member corresponds to at least one of a buff cleaning member and a pencil cleaning member that clean the substrate.
